(19) United States
(12) Patent Application Publication
(10) Pub. No.: US 2009/0128215 A1
(43) Pub. Date: May 21, 2009

(54) LEVEL SHIFTER, INTERFACE DRIVING CIRCUIT AND IMAGE DISPLAYING SYSTEM

(75) Inventor: Fu-Yuan HSUEH, Bade City (TW)

Correspondence Address: VENABLE LLP, P.O. BOX 34385, WASHINGTON, DC, 20043-9998, US

(73) Assignee: TPO DISPLAYS CORP., Chu-Nan (TW)

(21) Appl. No.: 12/261,811

(22) Filed: Oct. 30, 2008

(30) Foreign Application Priority Data
Nov. 15, 2007 (TW) 96143318

(51) Int. Cl. H03L 5/00

(52) U.S. Cl. 327/333

(57) ABSTRACT

The present invention relates to a level shifter for receiving a control signal to produce a driving voltage, comprising: a storage capacitor, one end of the storage capacitor coupled to the control signal and a reference voltage, another end of the storage capacitor coupled to the driving voltage and a assisting voltage; and a set of selecting switches for selecting one of the driving voltage and the assisting voltage to two ends of the storage capacitor, so that the storage capacitor is capable of boosting the voltage level of the control signal while the two ends of the storage capacitor coupled to the control signal and the driving voltage. The present invention further provides an interface driving circuit and an image displaying system.

### FIELD OF THE INVENTION

The present invention relates to a level shifter, an interface driving circuit and an image display system, and more particularly to a level shifter, an interface driving circuit and an image display system capable of controlling the voltage level.

### BACKGROUND OF THE INVENTION

In a typical electronic system, the control signal is always transmitted at a low level, and is converted to a high level signal by a level shifter before being transmitted to a back load circuit, so as to drive the back load circuit.

Referring to FIG. 6, the configuration of circuit of a conventional level shifter in accordance with the prior art is schematically shown. The conventional level shifter includes PMOS transistors M1, M3 and NMOS transistors M2, M4, wherein an input signal V_{IN} is coupled to the NMOS transistor M2, and an inverse signal thereof is coupled to the NMOS transistor M4. The NMOS transistors M2 and M4 are connected in series with the PMOS transistors M1 and M3 respectively, and are further connected to a DC power V_{DD}.

When the input signal V_{IN} is low level, the NMOS transistor M2 is switched off and the NMOS transistor M4 would be switched on. In this case, the voltage level at point B is V_{SS}, so that the transistor M1 is switched on. The voltage level at point A is increased to V_{DD}, so that the transistor M3 is switched off. Accordingly, a driving transistor M6 is switched on and the voltage level of the output voltage signal V_{OUT} is V_{SS}.

On the other hand, when the input signal V_{IN} is high level, the transistor M2 would be switched on and the transistor M4 is switched off gradually. The voltage level at point A is decreased to V_{SS}, hence the transistor M3 is switched on. The voltage level at point B is accordingly increased to V_{DD}, which makes the transistor M1 be switched off gradually. In this case, a driving transistor M5 is switched on and the voltage level of the output voltage signal V_{OUT} is also boosted to V_{DD}.

Nevertheless, the transmission of a control signal at high level may result in a significant loss of power. In view of this, the handy device is always designed to standby at a power-saving mode, or to operate with a control signal of low power. For example, the voltage level of the control signal, Main Clock (MCK), for the interface driving circuit of a handy device is required to be decreased to about 1.3V from conventional 2.5V since the power consumption of the thin film transistor liquid crystal display (TFT LCD) adopted therein is relatively large. For the conventional level shifter, however, such control signal of a voltage level of 1.3V fails to drive an output voltage signal, of a voltage level of 5V typically, under the originally high operation frequency.

FIG. 7 shows a further configuration of conventional interface driving circuit in accordance with the prior art, which includes two sets of level shifters 51, 52 that are connected in parallel, a non-synchronous level shifter 53 for horizontal signal synchronization (Hsync) and a logic circuit 54 for producing a reset pulse. Such interface driving circuit produces a plurality of output voltage signals, and a plurality of switches 55 select one voltage signal thereamong to the output circuit 56.

The interface driving circuit shown in FIG. 7 is capable of producing an output voltage signal of high voltage level utilizing the control signal MCK of low voltage level. Nevertheless, such driving circuit is not applicable in the handy device of small size due to its huge configuration involving three sets of level shifters to produce the voltage signal to output.

### SUMMARY OF THE INVENTION

It is an object of the present invention to provide a level shifter, an interface driving circuit and an image display system, which adopts a control signal of low voltage level to control and drive an output voltage signal of high voltage level.

For achieving the foregoing object, the present invention provides a level shifter for receiving a control signal to produce a driving voltage, comprising: a storage capacitor having one end coupled to said control signal and a reference voltage and having a further end coupled to said driving voltage and an assisting voltage; and a set of selective switches for selecting one of said control signal and said reference signal to said end of said storage capacitor, and selecting one of said driving voltage and said assisting voltage to said further end of said storage capacitor; wherein said set of selective switches select said reference voltage and said assisting voltage to the two ends of said storage capacitor in such a way that said voltage level of said control signal is boosted by said storage capacitor while said storage capacitor is coupled to said control signal and said driving voltage at the two ends thereof.

The foregoing object of the present invention is achieved by providing an interface driving circuit for receiving a control signal and producing an output voltage signal, comprising: a level shifter receiving and boosting said control signal; and a driving circuit having an input for receiving said control signal that is boosted by said level shifter, and producing said output voltage signal; wherein said level shifter comprises: a storage capacitor; and a set of selective switches for selecting one of said reference voltage and an assisting voltage coupled to the two ends of said storage capacitor, and selecting said storage capacitor to be coupled between said control signal and said input of said driving circuit; wherein said set of selective switches select said reference voltage and said assisting voltage coupled to the two ends of said storage capacitor in such a way that said voltage level of said control signal is boosted by said storage capacitor while said storage capacitor is coupled between said control signal and said input of said driving circuit.

The foregoing object of the present invention is achieved by providing an image display system, comprising: an interface driving circuit for receiving a control signal and producing a output voltage signal, comprising: a level shifter receiving and boosting said control signal; and a driving circuit receiving said control signal that is boosted by said level shifter, and producing said output voltage signal; wherein said level shifter comprises: a storage capacitor; and a set of selective switches for selecting said reference voltage and an assisting voltage coupled to the two ends of said storage capacitor, and selecting said storage capacitor to be coupled between said control signal and said input of said driving circuit; wherein said set of selective switches select said reference voltage and said assisting voltage coupled to the two ends of said storage capacitor in such a way that said voltage level of said control signal is boosted by said storage capacitor while said storage capacitor is coupled between said control signal and said input of said driving circuit.

The level shifter, the interface driving circuit and the image display system of the present invention adopt an easy combination of a plurality of switches and a storage capacitor to effectively achieve the boosting of control signal, so as to drive the operation of rear driving circuit with a control signal of low voltage level and to output a output voltage signal of high voltage level.

While the foregoing object and features of the present invention are illustrated with reference to the accompanying drawings, it should be noted that the drawings and the embodiments are provided for illustration but not for limitation of the present invention.

### BRIEF DESCRIPTION OF THE DRAWINGS

FIG. 1 is a circuit diagram illustrating the configuration of the interface driving circuit according to an embodiment of the present invention;

FIG. 2A shows the configuration of the level shifter under a first operation mode according to the present invention;

FIG. 2B shows the configuration of the level shifter under a second operation mode according to the present invention;

FIG. 3 shows the waveform of the respective signals according to an embodiment of the present invention;

FIG. 4 shows the configuration of the display panel according to an embodiment of the present invention;

FIG. 5 shows the configuration of the image display system according to an embodiment of the present invention;

FIG. 6 is a circuit diagram illustrating the configuration of a conventional level shifter in accordance with the prior art; and

FIG. 7 is a circuit diagram illustrating the configuration of a further conventional level shifter in accordance with the prior art.

### DETAILED DESCRIPTION OF THE EMBODIMENTS

With reference to the following disclosures combined with the accompanying drawings, the level shifter, the interface driving circuit and the image display system according to the present invention are illustrated and understood.

The present invention relates to an interface driving circuit which receives an input control signal of low level by a level shifter that is combined with a driving circuit to produce an output voltage signal of high level.

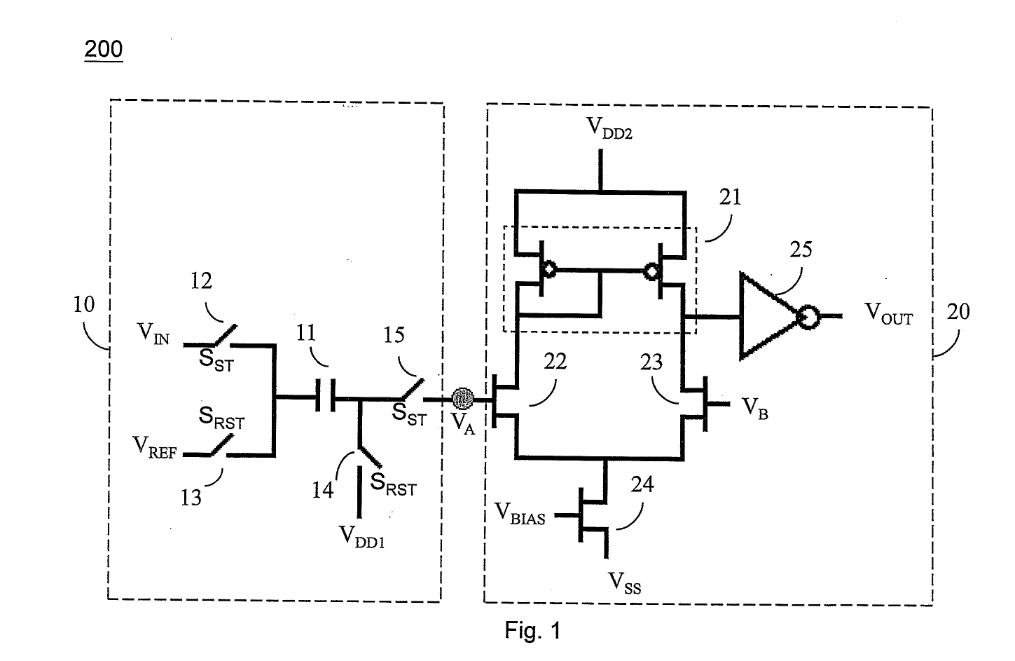

Referring to FIG. 1, the configuration of the interface driving circuit according to an embodiment of the present invention is illustrated. The interface driving circuit 200 includes a level shifter 10 and a driving circuit 20. The level shifter 10 is configured to receive a control signal V_{IN} of high voltage level (V_{IN-H}) or of low voltage level (V_{IN-L}), and to produce a driving voltage V_{A} by boosting the control signal V_{IN}. The driving voltage V_{A} is supplied to the driving circuit 20 so as to drive the driving circuit 20 to produce an output voltage signal V_{OUT} of a nominal high voltage level.

The level shifter 10 includes a storage capacitor 11 and four switches 12, 13, 14 and 15. The switches 13 and 14 are one set of switches that receive the same switching signal S_{RST} for synchronous operation, and are configured to charge the storage capacitor 11. The switches 12 and 15 are the further one set of switches that receive the same switching signal S_{ST} for synchronous operation, and are configured to control the storage capacitor 11 to produce the driving signal V_{A}. In the present embodiment, the switches 13, 14 and the switches 12, 15 are operated inversely, i.e. the switching signal S_{RST} and the switching signal S_{ST} are compensated with each other, so that the level shifter 10 is capable of operating in two different modes.

For the first operation mode, the storage capacitor 11 is charged with a reference voltage V_{REF} and an assisting voltage V_{DD1}, and thereby boosts the storage capacitor 11 to a predetermined voltage level. As to the second operation mode, the storage capacitor 11, which is already boosted under the first operation mode, would receive the control signal V_{IN}, and produce a driving voltage V_{A} by adding the predetermined voltage level to the control signal V_{IN}.

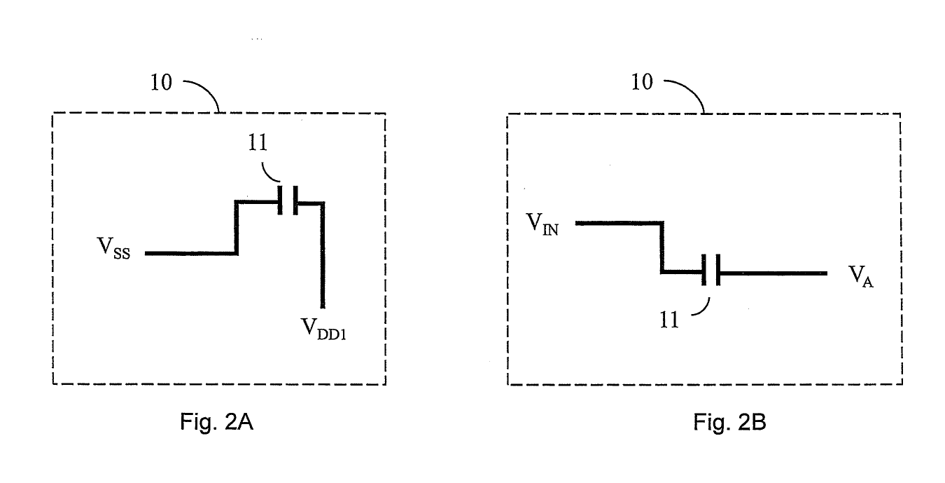

FIG. 2A shows the configuration of the level shifter 10 under the first operation mode according to the present invention. Under the first operation mode, the switches 13 and 14 are switched on, while the switches 12 and 15 are switched off. In this case, the storage capacitor 11 may be coupled to the reference voltage V_{REF} through the switch 13 at one end thereof, and to the assisting voltage V_{DD1} through the switch 14 at the other end. Moreover, the storage capacitor 11 is disconnected from the driving circuit 20, and hence no driving voltage V_{A} is output thereby. Accordingly, the storage capacitor 11 is held at a predetermined voltage level, V_{DD1}-V_{REF}, under the first operation mode.

FIG. 2B shows the configuration of the level shifter under the second operation mode according to the present invention. Under the second operation mode, the switches 13 and 14 are switched off, while the switches 12 and 15 are switched on. In this case, the storage capacitor 11 would be disconnected from the reference voltage V_{REF} and the assisting voltage V_{DD1}. The storage capacitor 11 receives the control signal V_{IN} and outputs a boosted driving voltage V_{A} to the driving circuit 20. Since the storage capacitor 11 is pre-boosted to the voltage level V_{DD1}-V_{REF}, the driving signal V_{A} output therefrom would be of a voltage level of:

V_{A-L}=V_{IN-L}+(V_{DD1}−V_{REF}); and

V_{A-H}=V_{IN-H}+(V_{DD1}−V_{REF}),

wherein V_{A-L} is referred to the driving signal V_{A} of low voltage level, and V_{A-H} is referred to the driving signal V_{A} of high voltage level.

Referring back to FIG. 1, the driving circuit 20 is an amplifying circuit for producing an output voltage signal V_{OUT} of sufficiently high voltage level. According to one embodiment of the present invention, the driving circuit 20 is a double-ended input amplifier with a current mirror. The driving circuit 20 includes a current mirror 21, a first driving transistor 22, a second driving transistor 23, a bias transistor 24 and an inverter 25. Moreover, the driving circuit 20 is coupled to a DC power V_{DD2} to produce the output voltage signal V_{OUT}.

The first driving transistor 22 is connected in series between the input of current mirror 21 and the bias transistor 24, while the second driving transistor 23 is connected in series between the output of current mirror 21 and the bias transistor 24. The gate of the first driving transistor 21 is controlled by the driving voltage V_{A} output from the level shifter 10, and the gate of the second driving transistor 23 is controlled by a base voltage V_{B}. In this case, the value of the output voltage signal V_{OUT} is controllable via the relative relation of high or low voltage level of the driving voltage V_{A} and the base voltage V_{B}. The bias transistor 24 receives a bias voltage V_{BIAS} to control the current passing through the current mirror 21, so as to further control the operation frequency of the driving circuit 20.

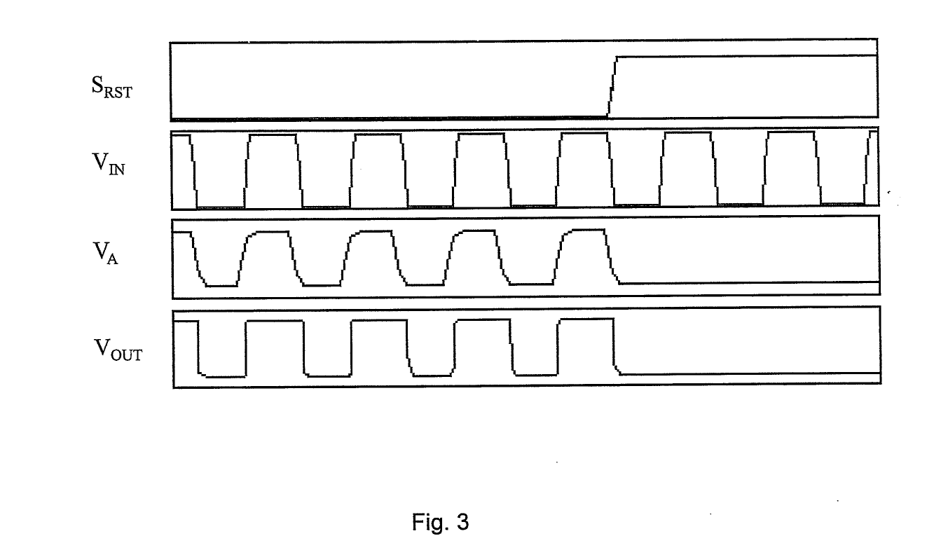

FIG. 3 shows the waveform of the respective signals according to an embodiment of the present invention. Referring FIGS. 1 to 3, the reference voltage V_{REF} may be a grounding voltage V_{SS}, and hence the voltage level of the reference voltage V_{REF} is termed as 0V. The control signal V_{IN} has a high voltage level of 1.65V and a low voltage level of 0V, while the assisting voltage V_{DD1} has a voltage level of 1.65V. Accordingly, the voltage level of the driving voltage V_{A} is ranged from (0+1.65)V to (1.65+1.65)V, i.e. from 1.65V to 3.3V, and the base voltage V_{B} is a voltage of an intermediate value within the range of 1.65V to 3.3V.

As shown in FIG. 3, referring to FIGS. 1, 2A and 2B, in case of the switching signal S_{RST} of a high voltage level (the logic 1), the driving voltage V_{A} as well as the output voltage signal V_{OUT} are both of low voltage level (the logic 0) since the storage capacitor 11 is disconnected from the driving circuit 20. As the switching signal S_{RST} is a low voltage level (the logic 0), the switching signal S_{ST} is a high voltage level (the logic 1), so that the storage capacitor 11 may receive the control signal V_{IN} and output the driving voltage V_{A}, and thereby the driving circuit 20 is driven to output the voltage signal V_{OUT}.

When the control signal V_{IN} is low voltage level, i.e. a voltage level of 0V, the storage capacitor 11 would output a driving voltage V_{A} having a voltage level of 1.65V so as to turn off the first driving transistor 22. The output voltage signal V_{OUT} is inverted by the inverter 25 so as to output a low voltage level. When the control signal V_{IN} is high voltage level, i.e. a voltage level of 1.65V, the storage capacitor 11 would output a driving voltage V_{A} having a voltage level of 3.3V so as to turn on the first driving transistor 22. The output voltage signal V_{OUT} is inverted by the inverter 25 so as to output a high voltage level of 5V.

Based on the mentioned, the level shifter, the interface driving circuit and the image display system of the present invention adopt an easy combination of a plurality of switches and a storage capacitor to effectively achieve the boosting of control signal, so as to drive the operation of rear driving circuit with a control signal of low voltage level (e.g. 1.65V) and to output a voltage signal having a high voltage level of about 5V.

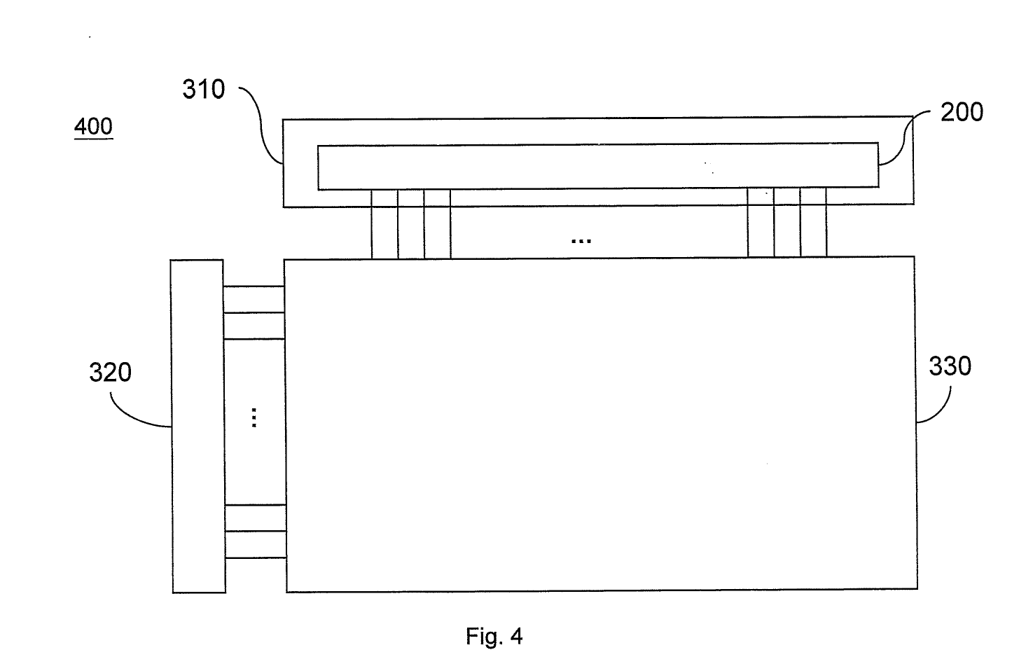

FIG. 4 shows the configuration of the display panel system according to an embodiment of the present invention. In the present embodiment, the display panel 400, which is a part of an electronic device, includes a horizontal driving circuit 310, a vertical driving circuit 320 and a display matrix 330. Wherein, the horizontal driving circuit 310 includes the interface driving circuit 200 which receives the control signal V_{IN} for the level shifter 10 and the driving circuit 20 to produce the output voltage signal V_{OUT}. The vertical driving circuit 320 is configured to control the connection between the horizontal driving circuit 310 and the display matrix 330, so as to provide the output voltage signal V_{OUT} to the display matrix 330 and to control the luminance of the display matrix 330.

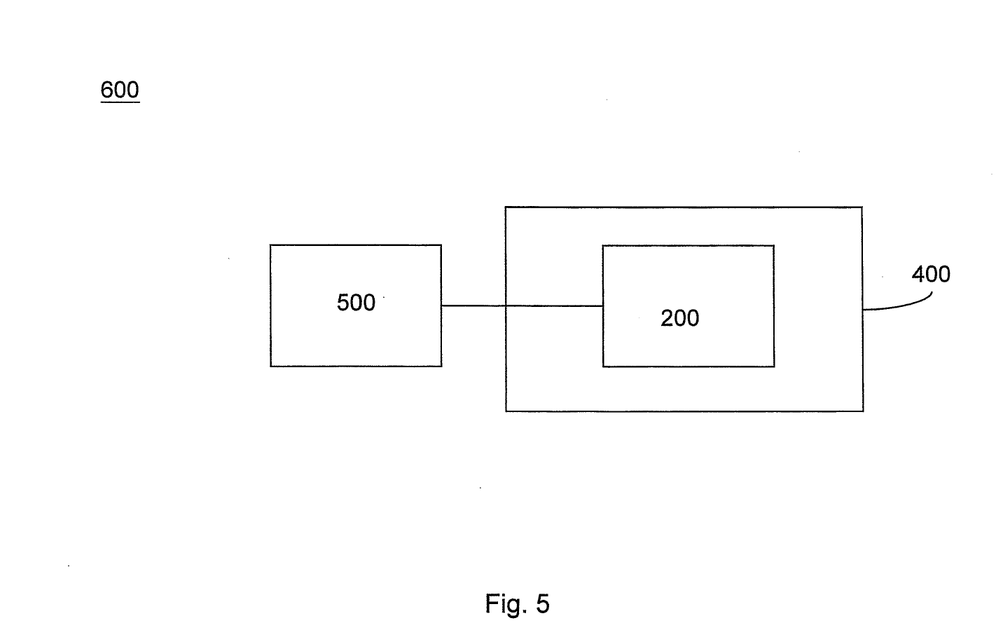

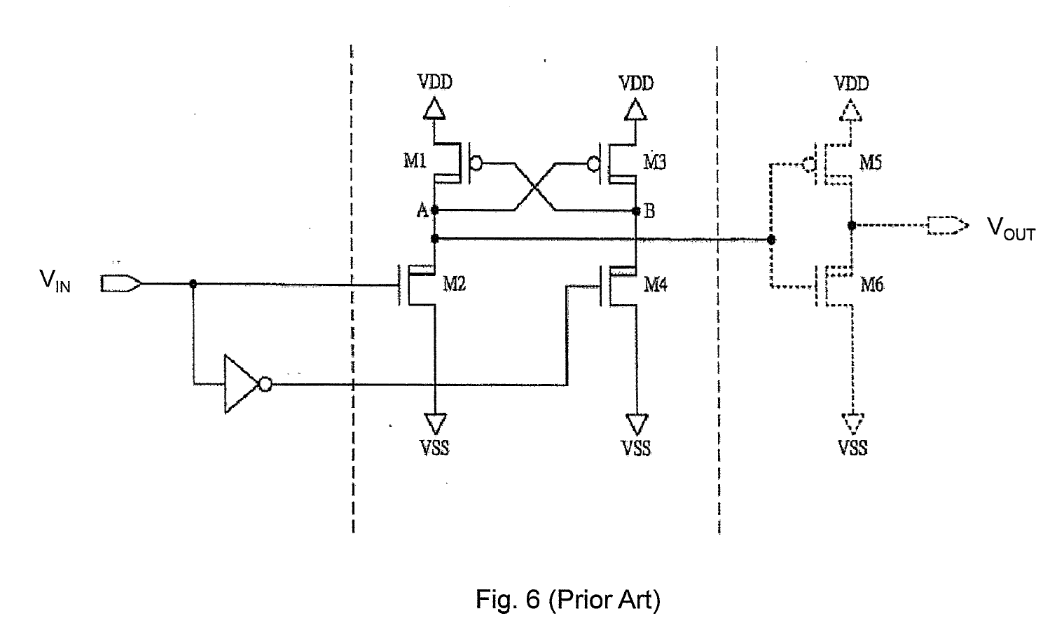

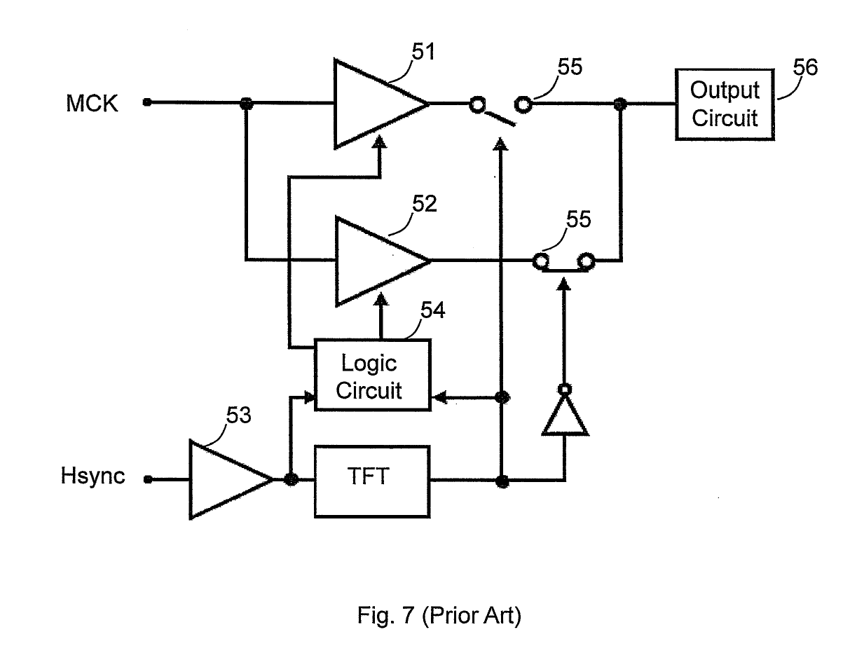

FIG. 5 shows the configuration of the image display system according to an embodiment of the present invention. In the present embodiment, the image display system 600 includes the display panel 400 combined with the interface driving circuit 200 and a power supply 500. Wherein, the power supply 500 is coupled to the display panel 400 for supplying the display panel 400 with power. According to the present invention, the image display system 600 may be a mobile phone, a digital camera, a personal digital assistant, a notebook, a personal computer, a television, a global positioning system, an automotive display, an aviation display, a digital picture frame or a handy DVD player.

While the invention has been described by way of examples and in terms of preferred embodiments, it is to be understood that various changes, substitutions, and alterations can be made herein without departing from the spirit and scope of the invention as defined by the appended claims.

What is claimed is:

1. A level shifter for receiving a control signal to produce a driving voltage, comprising:
a storage capacitor having one end coupled to said control signal and a reference voltage and having a further end coupled to said driving voltage and an assisting voltage; and
a set of selective switches selecting one of said control signal and said reference signal to said end of said storage capacitor, and selecting one of said driving voltage and said assisting voltage to said further end of said storage capacitor;
wherein said set of selective switches select said reference voltage and said assisting voltage to the two ends of said storage capacitor in such a way that said voltage level of said control signal is boosted by said storage capacitor while said storage capacitor is coupled to said control signal and said driving voltage at the two ends thereof.

2. The level shifter of claim 1, wherein said set of switches comprises a first set of switches for controlling said storage capacitor to receive said reference voltage and said assisting voltage at the two ends thereof respectively, and a second set of switches for controlling said storage capacitor to receive said control signal and to output said driving voltage at the two ends thereof respectively.

3. The level shifter of claim 1, wherein said first set of switches and said second set of switches are operated inversely.

4. The level shifter of claim 1, wherein said reference voltage is a grounding voltage.

5. An interface driving circuit for receiving a control signal and producing a output voltage signal, comprising:
a level shifter receiving and boosting said control signal; and
a driving circuit having an input for receiving said control signal that is boosted by said level shifter, and producing said output voltage signal;
wherein said level shifter comprises:
a storage capacitor; and
a set of selective switches for selecting one of said reference voltage and an assisting voltage to the two ends of said storage capacitor, and selecting said storage capacitor to be coupled between said control signal and said input of said driving circuit;
wherein said set of selective switches selects said reference voltage and said assisting voltage coupled to the two ends of said storage capacitor in such a way that said voltage level of said control signal is boosted by said storage capacitor while said storage capacitor is coupled between said control signal and said input of said driving circuit.

6. The interface driving circuit of claim 5, wherein said set of switches comprises a first set of switches for controlling said storage capacitor to receive said reference voltage and said assisting voltage at the two ends thereof respectively, and a second set of switches for controlling said storage capacitor to receive said control signal and to output said driving voltage at the two ends thereof respectively.

7. The interface driving circuit of claim 5, wherein said first set of switches and said second set of switches are operated inversely.

8. The interface driving circuit of claim 5, wherein said reference voltage is a grounding voltage.

9. The interface driving circuit of claim 5, wherein said driving circuit is further connected to a DC power to receive a DC voltage and produce said output voltage signal.

10. The interface driving circuit of claim 5, wherein said driving circuit is a dual-input current mirror amplifier having a first driving transistor and a second driving transistor respectively connected to a current mirror at the two ends thereof, and wherein said first driving transistor receives said driving voltage at the gate thereof while said second driving transistor receives a base voltage at the gate thereof and said output voltage signal is output at the connection of said second driving transistor and said current mirror.

11. The interface driving circuit of claim 10, wherein said output voltage signal is a high voltage level when said driving voltage is greater than said base voltage.

12. The interface driving circuit of claim 10, wherein said output voltage signal is a low voltage level when said driving voltage is less than said base voltage.

13. The interface driving circuit of claim 10, wherein the connection of said second driving transistor and said current mirror is further connected to an inverter for outputting an inverse signal of said output voltage signal.

14. The interface driving circuit of claim 10, wherein said first driving transistor and said second driving transistor are connected to a bias transistor for adjusting a current passing through said first driving transistor and said second driving transistor.

15. The interface driving circuit of claim 14, wherein said bias transistor is connected to a bias power at the gate thereof for adjusting said current passing through said first driving transistor and said second driving transistor.

16. An image display system, comprising:
an interface driving circuit for receiving a control signal and producing an output voltage signal, comprising:
a level shifter receiving and boosting said control signal; and
a driving circuit receiving said control signal that is boosted by said level shifter, and producing said output voltage signal;
wherein said level shifter comprises:
a storage capacitor; and
a set of selective switches selecting one of a reference voltage and an assisting voltage coupled to the two ends of said storage capacitor, and selecting said storage capacitor to be coupled between said control signal and said input of said driving circuit;
wherein said set of selective switches selects said reference voltage and said assisting voltage to the two ends of said storage capacitor in such a way that said voltage level of said control signal is boosted by said storage capacitor while said storage capacitor is coupled between said control signal and said input of said driving circuit.

17. The image display system of claim 16, further comprising a display panel, wherein said interface driving circuit is embodied as a part of said display panel.

18. The image display system of claim 17, further comprising a power supply that is coupled to said display panel and supply the power thereto.

19. The image display system of claim 16, wherein said image display system is one selected from a mobile phone, a digital camera, a personal digital assistant, a notebook, a personal computer, a television, a global positioning system, an automotive display, an aviation display, a digital picture frame and a handy DVD player.
